(19) United States
(12) Patent Application Publication
(10) Pub. No.: US 2017/0154926 A1
(43) Pub. Date: Jun. 1, 2017

(54) 3D CROSS-POINT ARRAY AND PROCESS FLOWS

(71) Applicant: Fu-Chang Hsu, San Jose, CA (US)

(72) Inventor: Fu-Chang Hsu, San Jose, CA (US)

(21) Appl. No.: 15/360,896

(22) Filed: Nov. 23, 2016

Related U.S. Application Data
(60) Provisional application No. 62/260,307, filed on Nov. 26, 2015.

(51) Int. Cl. H01L 27/24; H01L 45/00

(52) U.S. Cl. CPC H01L 27/2481; H01L 45/1233; H01L 45/1608; H01L 45/1675

(57) ABSTRACT

Three-dimensional cross-point array and process flows. In an exemplary embodiment, a method is provided that includes forming stacked layers, performing a first lithography operation on the stacked layers to form cell columns, and performing a second lithography operation on the stacked layers to form first vertical openings that are filled with first conductor layers to form one or more word line connections in a first direction. The method also includes performing a third lithography operation on the stacked layers to form second vertical openings that are filled with second conductor layers to form one or more bit line connections in a second direction.

### PRIORITY

This application claims the benefit of priority based upon U.S. Provisional patent application having Application No. 62/260,307, filed on Nov. 26, 2015, and entitled “3D CROSS-POINT ARRAY PROCESS FLOW,” which is hereby incorporated herein by reference in its entirety.

### FIELD OF THE INVENTION

The exemplary embodiments of the present invention relate generally to the field of semiconductors and integrated circuits, and more specifically to memory and storage devices.

### BACKGROUND OF THE INVENTION

A conventional 3D cross-point array architecture creates a three-dimensional checkerboard where memory cells sit at the intersection of word lines and bit lines, thus allowing the cells to be addressed individually. The 3D cross-point array has at least one drawback in that its word lines and bit lines run in alternate directions in parallel planes associated with each layer. Thus, conventional processes use lithography and etch steps for each layer to form the array layer by layer. This significantly increases the process cost, especially since the lithography steps cannot be performed for the whole wafer at one time. It needs to be done by using a stepper thus significantly increasing the process time.

Furthermore, since conventional cross-point arrays are formed layer by layer there is a need to address misalignment between each layer's cell patterns. This misalignment can result in uneven and increased cell pitch and increased manufacturing costs when stacking more layers to form larger arrays. Thus, it is necessary to address all the critical dimensions that result from a layer by layer process, which results in complex and expensive manufacturing processes.

FIG. 1A shows a conventional cross-point array structure. For example, a cell in the first layer is formed by a memory element 101a and a selector 101b. The memory element 101a can be as resistive-switching material, phase-change material, or other suitable material. The selector 101b can be a diode to prevent leakage current. A cell in a second layer is formed by the memory element 102a and the selector 102b that may have the same direction as the first layer's cell or opposite direction. For example, the order could be reversed such that the order is selector 102a and memory element 102b. Also shown are conductor layers for bit lines 103a and word lines 103d. As illustrated in FIG. 1A, the word lines 103d and bit lines 103a run in alternate directions in parallel planes for each layer, thus the array needs to have the lithography and etching steps performed for each layer to form the array layer by layer.

With respect to misalignment problems, extra ‘enclosure’ design rules are used to control the dimensions shown at 110a and 110b to ensure that for each layer, the memory layers (e.g., 101a and 102a) and selector layers (e.g., 101b and 102b) properly align and land on the word line and bit line conductor layers. Therefore, the memory cell's X-direction's pitch may be increased from 111a to 111b, and the cell's Y-direction's pitch may be increased from 112a to 112b. As a result, the cell size is significantly increased to compensate for misalignment. Moreover, the misalignment of memory cells between two or more layers (e.g., shown at 113) may accumulate. Thus, when multiple layers are stacked, the misalignment from the lowest layer to the highest layer may be significant. This may cause severe connection problems for the upper or top layer.

FIG. 1B shows another conventional cross-point array that is similar to the previous array except that each layer has its own separate word lines 104 and bit lines 106 that run in different directions in the parallel planes for each layer. The array in FIG. 1B also needs to have the lithography and etching steps performed for each layer to form the array layer by layer.

Therefore, it is desirable to have a novel 3D cross point array and process flows to overcome the problems associated with conventional arrays.

### SUMMARY

In various exemplary embodiments, novel 3D cross-point arrays and associated novel process flows are disclosed. In various exemplary embodiments, the novel process flows utilize just three lithography steps to form novel 3D cross-point arrays that have significant alignment and cell pitch improvements over conventional 3D cross-point arrays.

The exemplary embodiments can be implemented in RRAM (Resistive Random-Access Memory), PCM (Phase-Change memory), MRAM (Magnetoresistive Random-Access Memory), FRAM (Ferroelectric Random-Access Memory), anti-fuse OTP NVM (One-Time-Programmable Non-Volatile Memory), and many others. Moreover, the exemplary embodiments can be implemented in any process, such as CMOS, FinFET, SOI (Silicon-On-Insulator), and many others.

In an exemplary embodiment, a method is provided that includes forming stacked layers, performing a first lithography operation on the stacked layers to form cell columns, and performing a second lithography operation on the stacked layers to form first vertical openings that are filled with first conductor layers to form one or more word line connections that run in a first direction. The method also includes performing a third lithography operation on the stacked layers to form second vertical openings that are filled with second conductor layers to form one or more bit line connections that run in a second direction, where the first and second directions run in parallel planes.

In an exemplary embodiment, a method is provided that includes forming stacked layers, performing a first lithography operation to form a photoresist mask on top of the stacked layers for cell columns, word lines and bit lines and etching through stacked layers to form the cell columns, the word lines and the bit lines. The method also includes filling space between the cell columns, the word lines and the bit lines with an insulator, and performing a second lithography operation on the stacked layers for the cell columns to form first vertical openings that are filled with first conductor layers to form one or more word line connections in a first direction. The method also includes performing a third lithography operation on the stacked layers for the cell columns to form second vertical openings that are filled with second conductor layers to form one or more bit line connections in a second direction.

In an exemplary embodiment, a 3D cross-point array is formed by performing the operations of forming stacked layers, performing a first lithography operation on the stacked layers to form cell columns, and performing a second lithography operation on the stacked layers to form first vertical openings that are filled with first conductor layers to form one or more word line connections in a first direction. The operations also includes performing a third lithography operation on the stacked layers to form second vertical openings that are filled with second conductor layers to form one or more bit line connections in a second direction.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIGS. 1A-B show conventional cross point array structures;

FIGS. 2A-Q show exemplary embodiments of process flows that form a cross point array structure in accordance with the embodiments of the invention;

FIGS. 3A-H show exemplary embodiments of process steps that form a cross point array structure with word line and bit line connections in accordance with the embodiments of the invention;

FIGS. 4A-D show exemplary embodiments of process steps that remove unconnected cell layers from the array structure shown in FIG. 3F;

FIG. 5 shows an exemplary embodiment of a method to form a cross-point array utilizing just three lithography steps in accordance with the present invention; and

FIG. 6 shows an exemplary embodiment of a method to form a cross-point array having word lines and bit lines that can be connected to peripheral circuitry in accordance with the present invention.

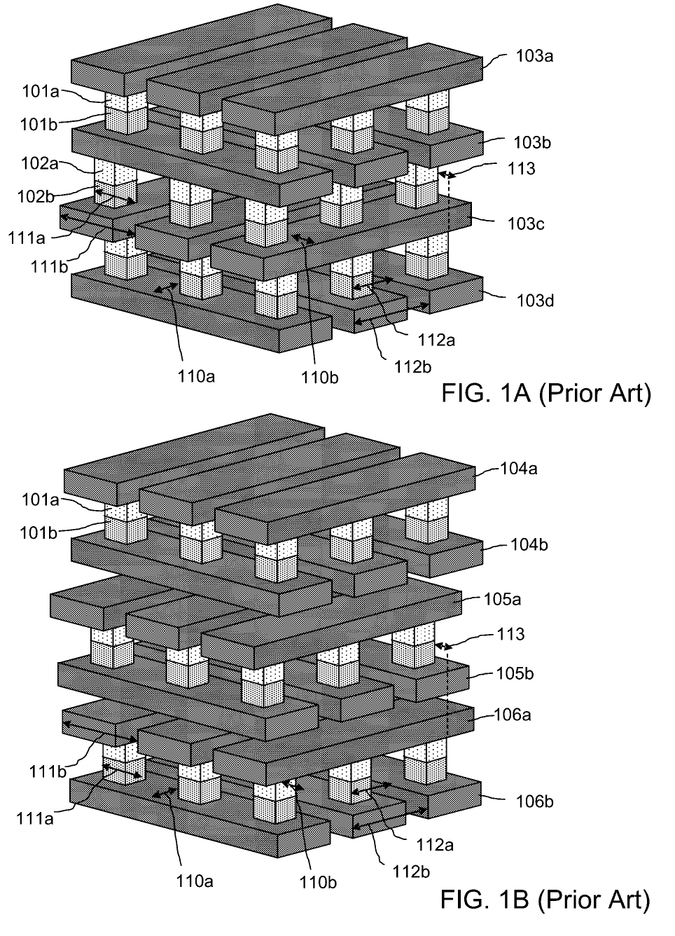

### DETAILED DESCRIPTION

Exemplary embodiments of the present invention are described herein in the context of processes for forming 3D cross-point arrays. Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, novel process flows are disclosed that reduce the number of lithography steps for manufacturing 3D cross-point arrays and result in arrays having significant alignment and cell pitch improvements over conventional 3D cross-point arrays. The disclosed process flows can be implemented in any product, technology, and process. For example, the exemplary embodiments can be implemented in RRAM (Resistive Random-Access Memory), PCM (Phase-Change memory), MRAM (Magnetoresistive Random-Access Memory), FRAM (Ferroelectric Random-Access Memory), anti-fuse OTP NVM (One-Time-Programmable Non-Volatile Memory), and many others. Moreover, the exemplary embodiments can be implemented in any process, such as CMOS, FinFET, SOI (Silicon-On-Insulator), and many others. A person skilled in the art shall recognize these variations shall remain in the scope of the embodiments of the invention.

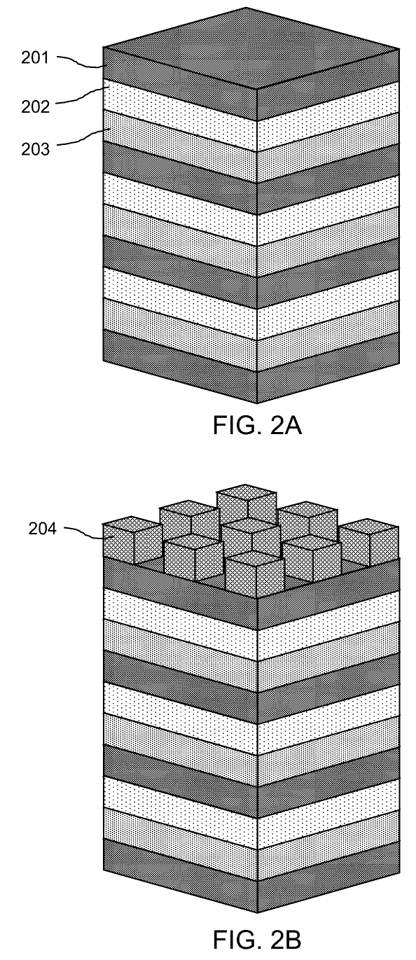

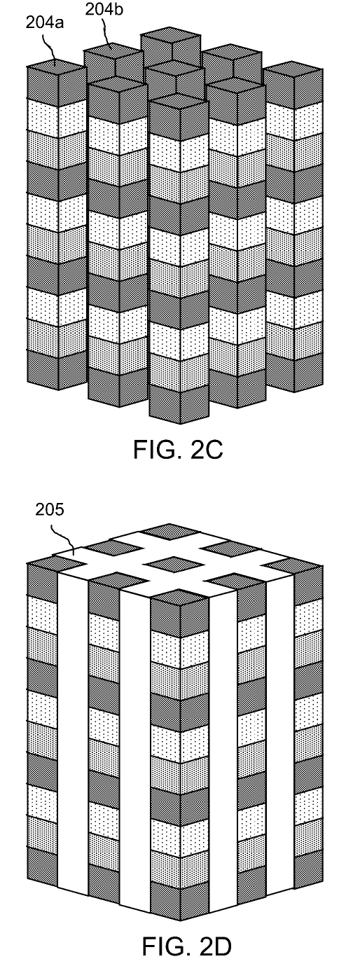

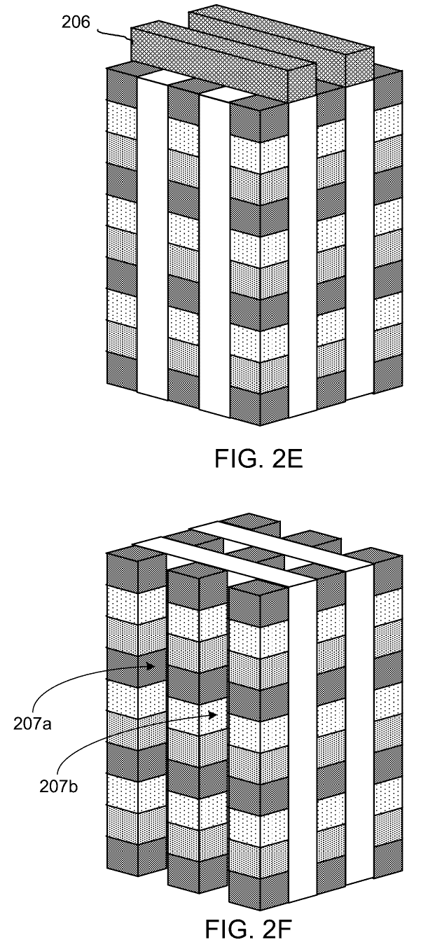

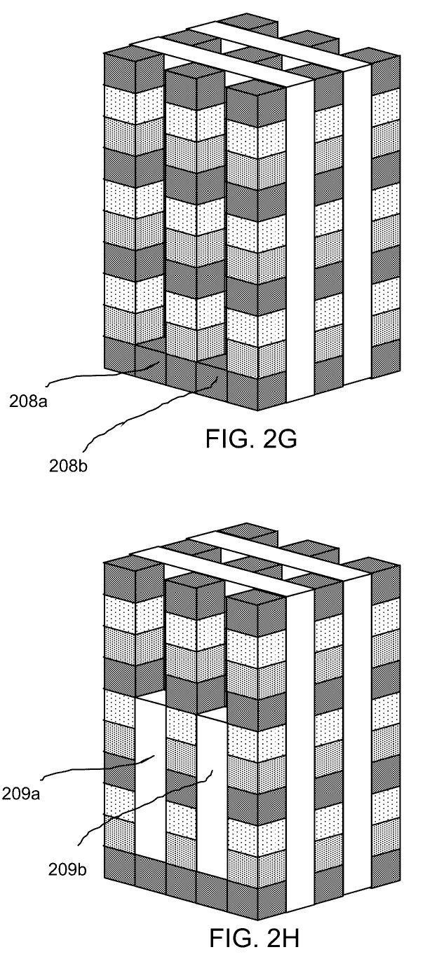

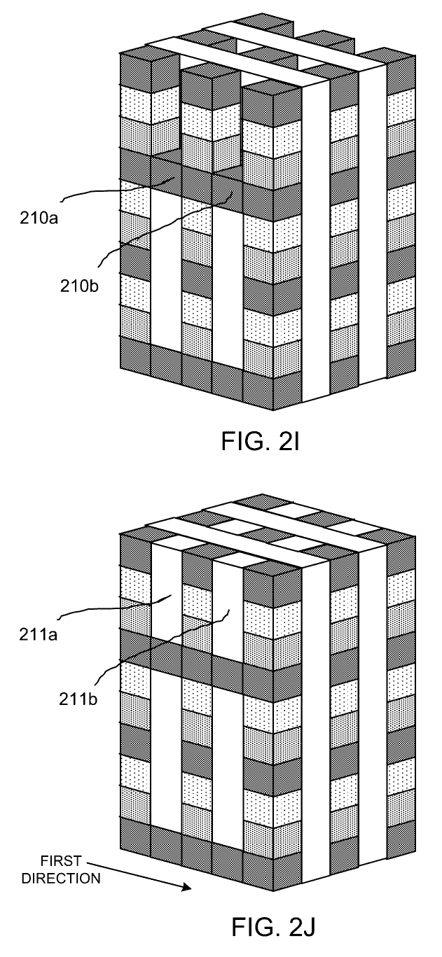

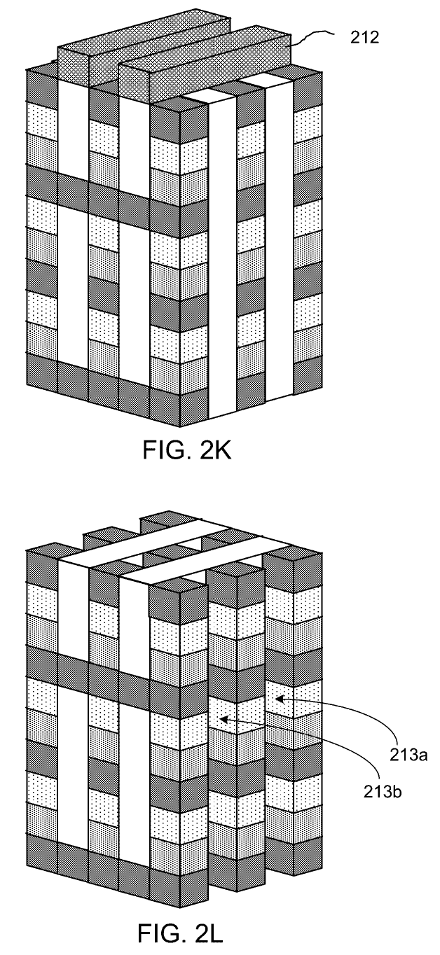

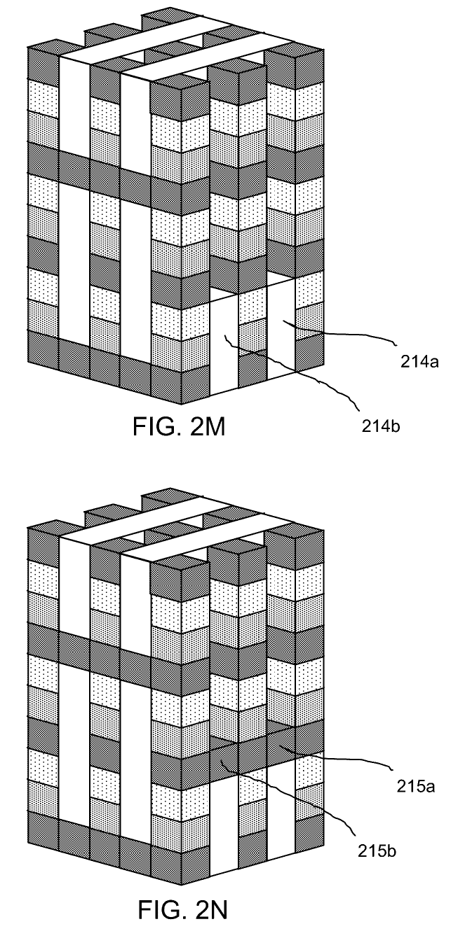

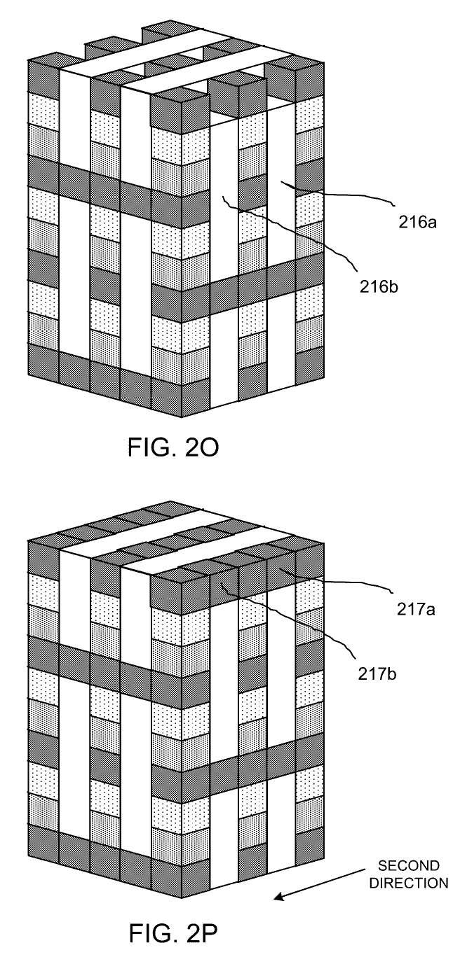

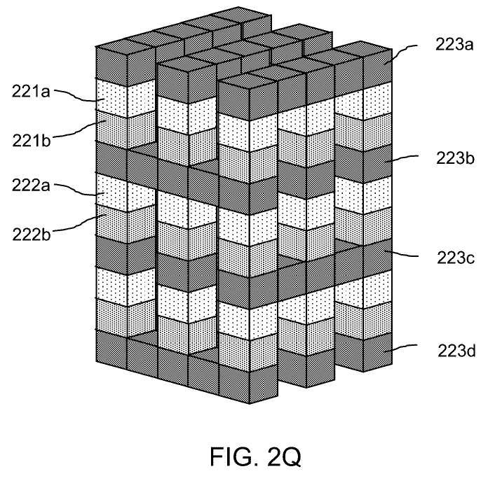

FIGS. 2A-Q show exemplary embodiments of novel process flows that form a 3D cross-point array structure in accordance with the embodiments of the invention. The process flows described with reference to FIGS. 2A-Q are exemplary and not limiting of the scope of the invention. Thus, the process flows may be modified according to the process and technology used and these variations are within the scope of the embodiments of the invention.

FIG. 2A shows an exemplary embodiment of a first process step (or operation) wherein multiple layers of material are deposited to form stacked layers. The materials used are dependent on the cell structure. For example, in one embodiment, a conductor layer 201 can be a polysilicon or metal and a memory element layer 202 can be a resistive-switching material for RRAM, chalcogenide for PCM, ferromagnetic material for MRAM, ferroelectric material for FRAM, dielectric layer for anti-fuse OTP, or other suitable material. A selector material layer 203 can be a P-N junction diode formed by P-type and N-type polysilicon layers, or Schottky diode formed by polysilicon and metal layers, or any other material having threshold behavior for the direction of current flow. The memory element layer 202 and selector layer 203 can contain single or multiple layers.

FIG. 2B shows an exemplary embodiment of a second process step wherein a first lithography operation is performed to form a photoresist mask 204 on top of the stacked layers.

FIG. 2C shows an exemplary embodiment of a third process step wherein an etching process is used to etch (e.g., form a trench) through all the stacked layers to form “cell columns” such as cell column 204a and cell column 204b. Etching all cell columns in this step produces precisely aligned and dimensioned cell columns (e.g., memory cells) that will result in an array with consistent cell pitch and orientation with respect to the word lines and bit lines. The process step also eliminates layer to layer misalignment. Thus, this process step aligns (or self-aligns) all the layers and associated memory cells in each column.

FIG. 2D shows an exemplary embodiment of a fourth process step wherein an insulator 205, such as oxide is deposited to fill the etched spaces between the columns shown in FIG. 2C.

FIG. 2E shows an exemplary embodiment of a fifth process step wherein a second lithography operation is performed to form a photoresist mask 206 on top of the stacked layers.

FIG. 2F shows an exemplary embodiment of a sixth process step wherein an etching process is used to etch away the insulator around the photoresist to form vertical holes (or openings) (e.g., 207a and 207b).

FIG. 2G shows an exemplary embodiment of a seventh process step wherein a first conductor layer (e.g., 208a and 208b) is deposited into the vertical holes. In an exemplary embodiment, the deposited conductor material connects to the conductor layer of the cell columns to form the first word line layer.

FIG. 2H shows an exemplary embodiment of an eighth process step wherein an insulator layer (e.g., 209a and 209b) is deposited into the vertical holes up to the next word line conductor layer.

FIG. 2I shows an exemplary embodiment of a ninth process step wherein a second conductor layer (e.g., 210a and 210b) is deposited into the vertical holes. In an exemplary embodiment, this second conductor layer connects to the conductor layer of the cell columns to form a second word line layer.

FIG. 2J shows an exemplary embodiment of a tenth process step wherein an insulator layer (e.g., 211a and 211b) is deposited into the vertical holes. Thus, the fifth through tenth process steps form word line layers the run in a first direction across the array. It should be noted that only two word line layers are shown but that in other embodiments, the above process steps can be used to form any number of word line layers.

FIG. 2K shows an exemplary embodiment of an eleventh process step wherein a third lithography operation is performed to form a photoresist mask 212 on top of the stacked layers.

FIG. 2L shows an exemplary embodiment of a twelfth process step wherein an etching process is used to etch away the insulator around the photoresist mask 212 to form vertical holes (or openings) (e.g., 213a and 213b).

FIG. 2M shows an exemplary embodiment of a thirteenth process step wherein an insulator layer (e.g., 214a and 214b) is deposited into the vertical holes up to a first bit line layer.

FIG. 2N shows an exemplary embodiment of a fourteenth process step wherein a conductor layer (e.g., 215a and 215b) is deposited into the vertical holes. In an exemplary embodiment, the deposited conductor may connect to the conductor layer of the cell columns to form the first bit line layer.

FIG. 2O shows an exemplary embodiment of a fifteenth process step wherein an insulator layer (e.g., 216a and 216b) is deposited into the vertical holes up to a second bit line layer.

FIG. 2P shows an exemplary embodiment of a sixteenth process step wherein a second conductor layer (e.g., 217a and 217b) is deposited into the vertical holes as shown. In an exemplary embodiment, the deposited conductor is connected to the conductor layer of the cell column to form the second bit line layer. Thus, the eleventh through sixteenth process steps form bit line layers the run in a second direction across the array. It should be noted that only two bit line layers are shown but that in other embodiments, the above process steps can be used to form any number of bit line layers.

FIG. 2Q shows an exemplary embodiment of the finished cross-point cell array structure after the novel process flows described above. For clarity, the insulator layers are removed so that the cell structure can be clearly seen. A cell in the first layer is formed by 221a and 221b and a cell in the second layer is formed by 222a and 222b. Also shown are word lines 223a and 223c and bit lines 223b and 223d for the first layer and second layer, respectively. As a result, the array structure is formed by only using three lithography steps. As can be seen, the word lines and bit lines run in different directions but in parallel planes. Furthermore, by forming all columns in one lithography operation (e.g., see FIG. 2C), the resulting array shown in FIG. 2Q has precisely aligned and dimensioned memory cells, word lines, and bit lines, with reduced or no misalignment and consistent cell pitch, which represents a significant improvement over conventional cross point arrays.

Therefore, in accordance with the exemplary embodiments disclosed, a cross-point array is formed using only three lithography steps; one for cell columns, one for word line patterns, and one for bit line patterns. The word lines and bit lines for each layer are formed by deposition instead of additional lithography steps and etching for each layer. By using this novel process, increasing the number of the 3D array layers will not increase the number of lithography steps but only the deposition steps, which significantly reduces the process time and cost over conventional processes. Furthermore, the resulting array has precisely aligned and dimensioned memory cells, word lines, and bit lines with reduced or no misalignment and consistent cell pitch.

### Novel 3D Cross-Point Array Structures

In various exemplary embodiments, novel 3D cross-point array structures are formed using the disclosed novel processes. The novel 3D cross-point arrays have several improvements and advantages over the conventional cross-point arrays as discussed below.

First, the 3D cross-point arrays formed by the novel processes disclosed herein have cell patterns that are self-aligned for all the multiple layers. For example, self-alignment occurs because the cell patterns of all the multiple layers are defined by one lithography step that forms the trench hole defining the cell columns and then deposits multiple layers into the trench hole. Thus, the cell patterns of multiple layers are all self-aligned. Conventional arrays that are formed layer by layer are not self-aligned and therefore need to address misalignment between each layer's cell patterns. Due to the self-aligning of the cell patterns, a 3D cross-point array formed using the disclosed novel processes can use the minimum design rule to achieve tighter pitch and reduced cell size when compared to conventional arrays formed by multiple individual lithography steps. For example, due to misalignments, the design rules for conventional arrays need to be increased in order to cover the misalignments. As a result, 3D cross-point arrays formed by the novel processes disclosed herein can have a cell size that is smaller than conventional arrays.

Second, the 3D cross-point arrays formed by the novel processes disclosed herein are configurable to have a higher number of stacked layers compared to conventional arrays. For example, because the 3D cross-point arrays formed by the novel processes disclosed herein define the cell patterns for all the multiple layers by using only three lithography steps, the manufacturing cost does not significantly increase when more layers are stacked. Therefore, the resulting array structures are highly suitable for high density products having, for example, 32 or 64 stacked layers. In comparison, convention arrays are formed by repeating lithography steps for each layer, and therefore the manufacturing costs drastically increase when stacking more layers. For example, each lithography step contains several steps including photoresist coating, bake, align and exposure, developing, etching, and strip photoresist. The exposure is done by using a stepper to repeatedly project the patterns on the wafer frame by frame. Therefore, the entire lithography operation is very time-consuming and costly.

Third, the 3D cross-point arrays formed by the novel processes disclosed herein can utilize more relaxed design rules than conventional arrays to achieve the same density. For example, conventional 3D cross-point arrays use a 20 nm process with 2 layer stacking to achieves 128 Gb density. In comparison, 3D cross-point arrays formed by the novel processes disclosed herein can use a 40 nm process with 8 layer stacking, or a 56 nm process with 16 layer stacking to achieve the same density. This significantly reduces the process challenge and cost and improves yield.

Fourth, the 3D cross-point arrays formed by the novel processes disclosed herein have only one critical dimension (CD) for the trench hole, (e.g., the cell column trench) while in conventional arrays each layer's cell patterns are all critical dimensions. Thus, the novel 3D cross-point arrays disclosed herein significantly reduce manufacturing costs and improve yield.

Fifth, the 3D cross-point arrays formed by the novel processes disclosed herein have more uniform cell pitch defined by single-patterning, while conventional arrays may require more expensive double-patterning and result in more uneven cell pitch. Because conventional arrays use processes, such as 20 nm, to achieve the density in demand, double-patterning lithography is used that is generally required for sub-30 nm process. The double-patterning lithography may cause uneven cell pitch which increases the process challenge for 3D array stacking. In addition, the manufacturing cost is significantly increased due to the double-patterning. In contrast, the 3D cross-point arrays formed by the novel processes disclosed herein can use more relaxed processes, such as 40 nm for example, and all the layers' patterns are self-aligned. Therefore, the resulting array has more uniform cell pitch and better yield.

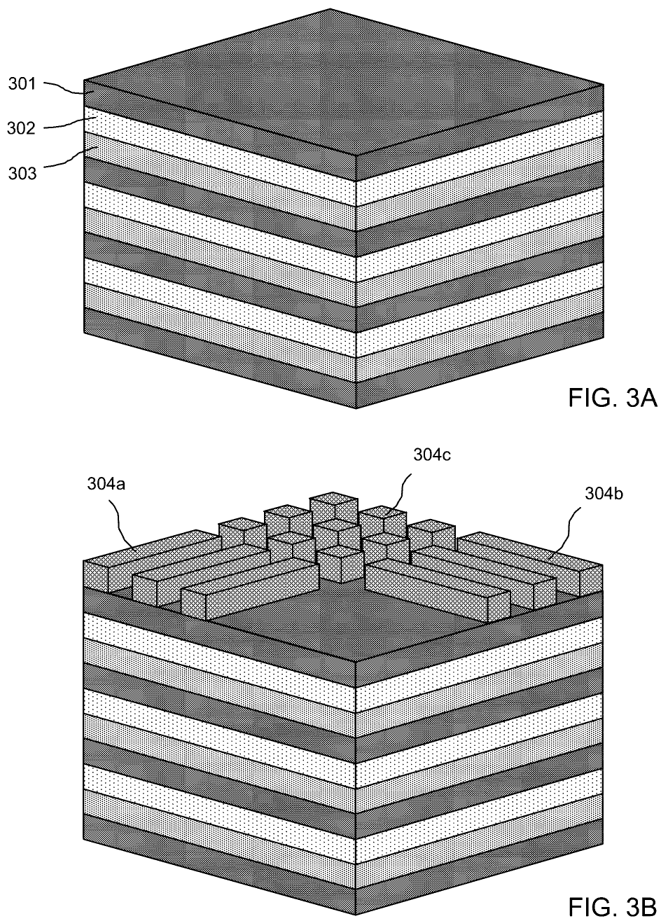

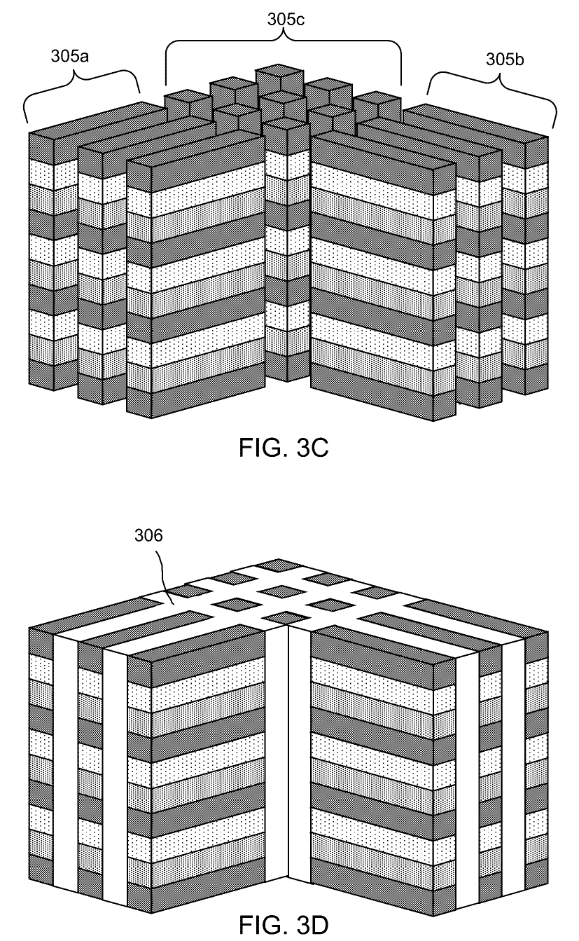

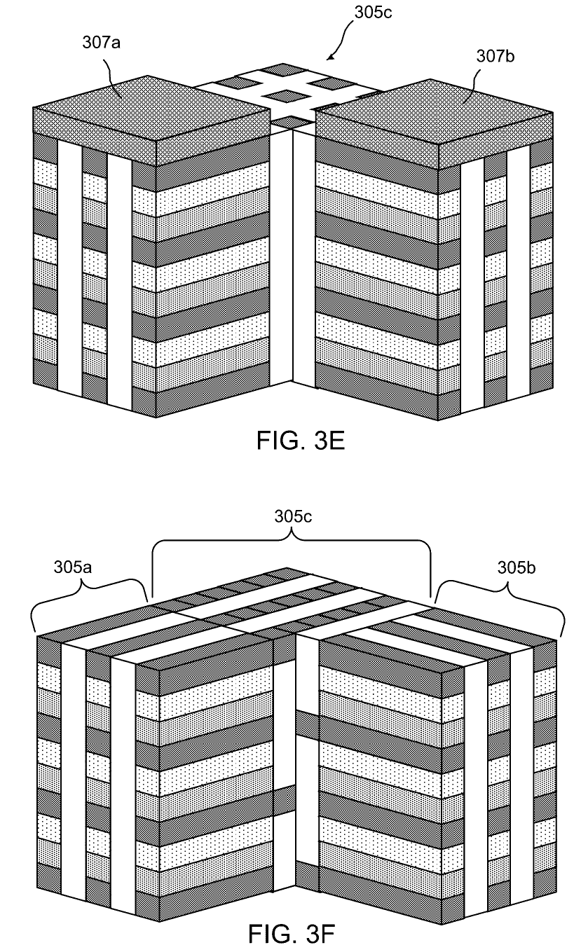

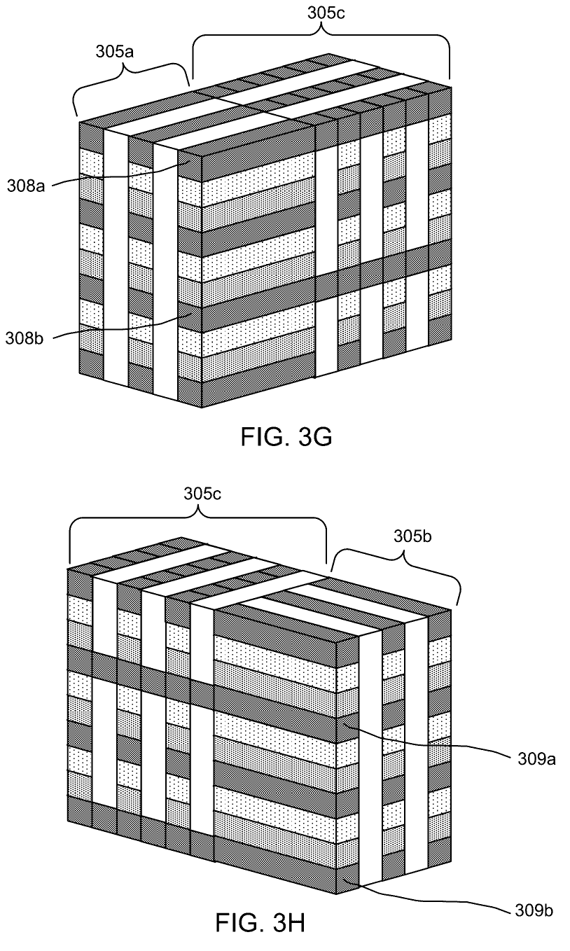

FIGS. 3A-H show exemplary embodiments of novel process flows that form a cross point array structure in accordance with the embodiments of the invention. For example, in an exemplary embodiment, the process steps are used to form word lines and bit lines of a cross-point array structure that can be connected to peripheral circuitry, such as decoder circuits.

FIG. 3A shows an exemplary embodiment of a first process step (or operation) wherein multiple layers of cell array materials, such as conductor layer 301, memory element layer 302, and selector layer 303 are deposited to form stacked layers.

FIG. 3B shows an exemplary embodiment of a second process step wherein lithography is used to form a photoresist on top of the stacked layers to define the word line pattern 304a, bit line pattern 304b, and cell column 304c as described above. In an exemplary embodiment, the region of cell column mask 304c is the same as shown in FIG. 2B above and occupies less than the full area of the stacked layers.

FIG. 3C shows an exemplary embodiment of a third process step wherein an etching process is performed by using the photoresist to etch through the stacked layers to form the word line patterns 305a, bit line patterns 305b, and cell columns 305c. Etching all cell columns, word lines, and bit lines, in this step produces precisely aligned and dimensioned cell columns (e.g., memory cells) that will result in an array with consistent cell pitch and orientation with respect to the memory cells, word lines, and bit lines. The process step also eliminates layer to layer misalignment. Thus, this process step aligns (or self-aligns) all the layers and associated memory cells, word lines, and bit lines in each column.

FIG. 3D shows an exemplary embodiment of a fourth process step wherein an insulator 306, such as oxide, is deposited to fill the etched spaces of the stacked layers.

FIG. 3E shows an exemplary embodiment of a fifth process step wherein lithography is used to form photoresist 307a and 307b on top of the stacked layers to cover the word line and bit line areas.

In an exemplary embodiment, the fifth process step can be performed at the same time as the process step performed and shown with reference to FIG. 2E where mask 206 is formed on the column area. After that, the process steps performed and shown in FIGS. 2F-P are performed to form the cell array in the cell column area 305c.

FIG. 3F shows an exemplary embodiment of the completed array structure after the above process steps are completed. For additional illustration, FIG. 3G shows an exemplary embodiment of the array structure with the bit line portion 305b removed. FIG. 3G illustrates how the cell columns 305c and the word lines (e.g., 308a and 308b) of the word line portion 305a are connected. FIG. 3H shows an exemplary embodiment of the array structure with the word line portion 305a removed. FIG. 3H illustrates how the bit lines 309a and 309b of the bit line portion 305b and the cell columns 305c are connected.

It should be noted that in word line portion 305a and bit line portion 305b, there are unconnected cell layers between the word lines and bit lines. This will not cause any problems because the unconnected word lines and bit lines are floating. Moreover, during operation, the connected word lines and bit lines are supplied with proper bias conditions to prevent current leakage. Therefore, there is no current leakage through the floating word lines and bit lines.

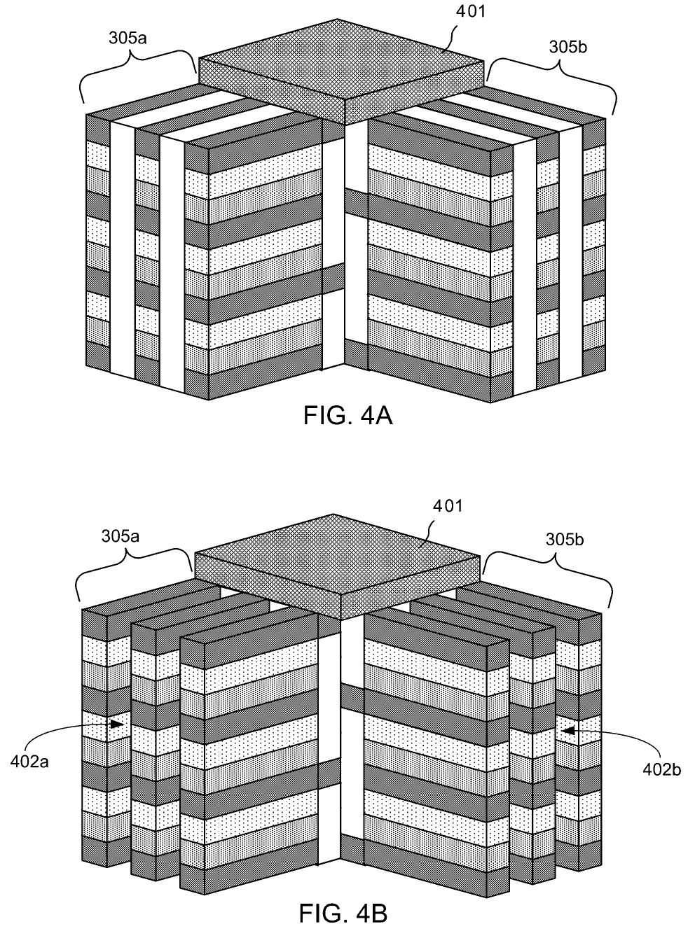

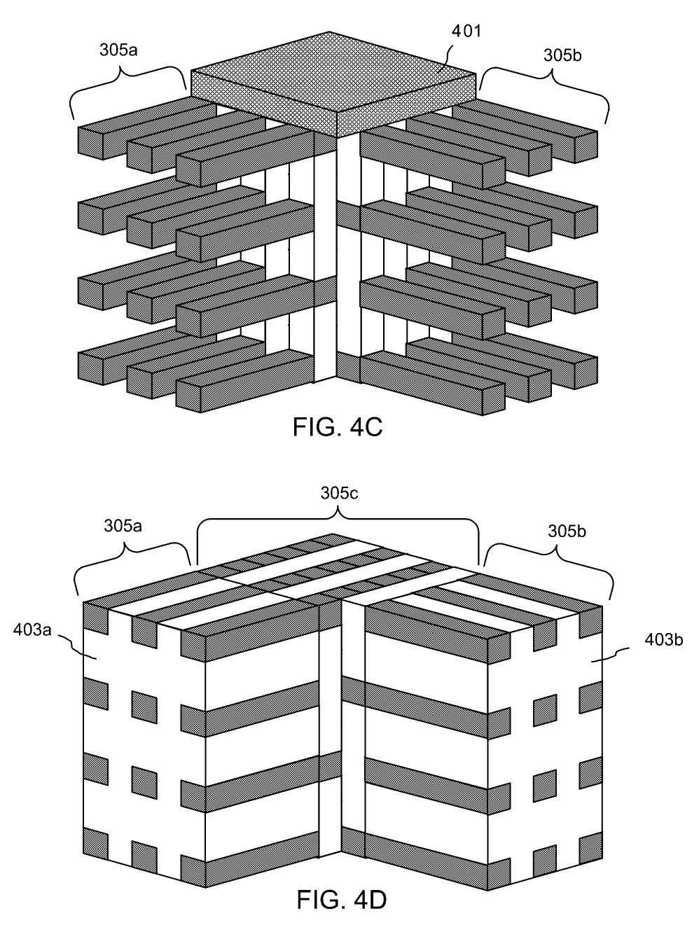

FIGS. 4A-D show exemplary embodiments of process steps that remove unconnected cell layers from the array shown in FIG. 3F.

FIG. 4A shows an exemplary embodiment of a first process step wherein lithography is used to form a photoresist mask 401 on top of the cell column portion of the array as shown in FIG. 3F.

FIG. 4B shows an exemplary embodiment of a second process step wherein an etching process is performed using the photoresist mask 401 to etch away the insulator in the word line portion 305a and bit line portion 305b to form slits 402a and 402b.

FIG. 4C shows an exemplary embodiment of a third process step wherein the cell layers between the word lines and bit lines are selectively etched away through the slits 402a and 402b.

FIG. 4D shows an exemplary embodiment of a third process step wherein an insulator layer, such as oxide, is deposited to fill the slits and the spaces between word lines and bit lines, as shown 403a and 403b. As a result, the word lines and bit lines are isolated by the insulator.

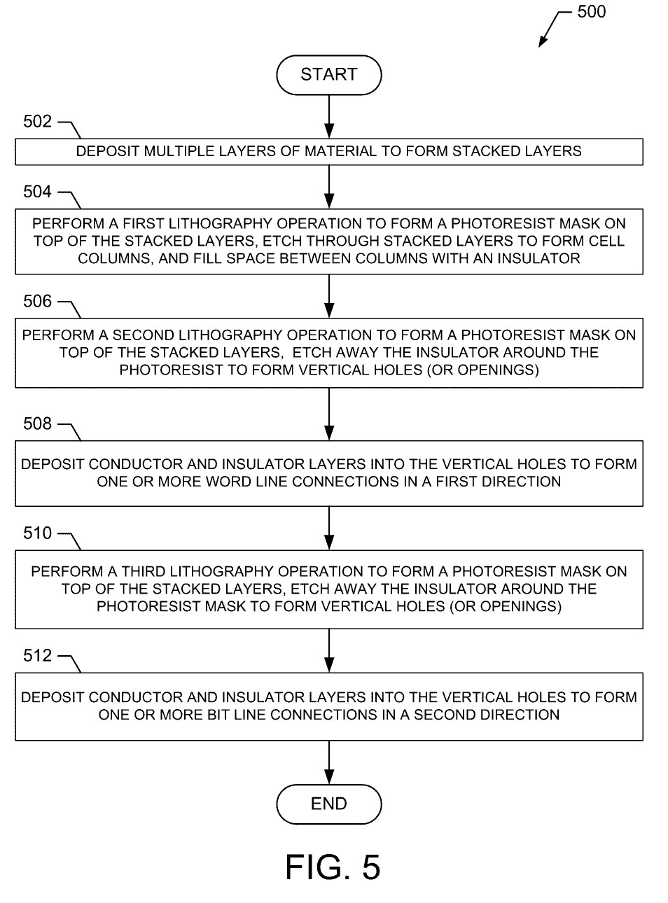

FIG. 5 shows an exemplary embodiment of a method 500 to form a cross-point array utilizing just three lithography steps in accordance with the present invention. In an exemplary embodiment, the method 500 is suitable for use to form the cross-point arrays shown in FIG. 2A-Q described above.

At block 502, multiple layers of material are deposited to form stacked layers. For example, in an exemplary embodiment, the first process step described with respect to FIG. 2A above is performed.

At block 504, a first lithography operation is performed to form a photoresist mask on the stacked layers, the stack layers are etched to form cell columns, and the space between the columns are filled with an insulator. For example, in an exemplary embodiment, the second through fourth process steps described with respect to FIG. 2B-D above are performed. Etching all cell columns in this step produces precisely aligned and dimensioned cell columns (e.g., memory cells) that will result in an array with consistent cell pitch and orientation with respect to the word lines and bit lines. The process step also eliminates layer to layer misalignment. Thus, this process step aligns (or self-aligns) all the layers and associated memory cells in each column.

At block 506, a second lithography operation is performed to form a photoresist mask on top of the stacked layers, the insulator around the photoresist is etched to form vertical holes (or openings). For example, in an exemplary embodiment, the fifth and sixth process steps described with respect to FIG. 2E-F above are performed.

At block 508, conductor and insulator layers are deposited into the vertical holes to form one or more word line connections in a first direction. For example, in an exemplary embodiment, the seventh through tenth process steps described with respect to FIG. 2G-J above are performed.

At block 510, a third lithography operation is performed to form a photoresist mask on top of the stacked layers and etch the insulator around the photoresist to form vertical holes (or openings). For example, in an exemplary embodiment, the eleventh and twelfth process steps described with respect to FIG. 2K-L above are performed.

At block 512, conductor and insulator layers are deposited into the vertical holes to form one or more bit line connections in a second direction. For example, in an exemplary embodiment, the thirteenth through sixteenth process steps described with respect to FIG. 2M-P above are performed.

Thus, the method 500 operates to form a cross-point array utilizing just three lithography steps in accordance with the present invention. It should be noted that the method 500 is exemplary and that any of the disclosed operations may be combined, rearranged, added to, deleted, and/or modified within the scope of the embodiments.

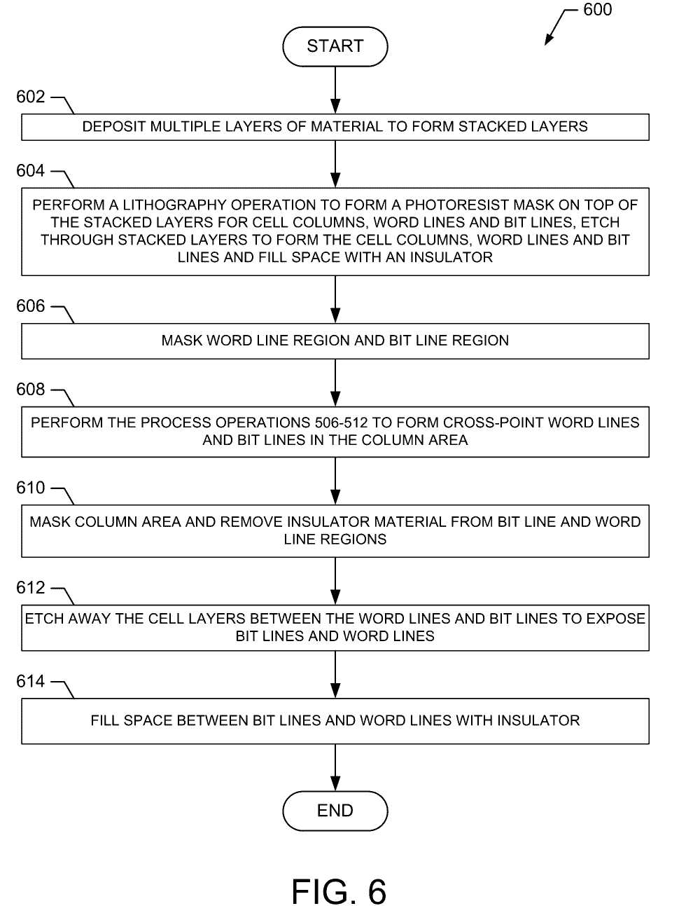

FIG. 6 shows an exemplary embodiment of a method 600 to form a cross-point array having word lines and bit lines that can be connected to peripheral circuitry in accordance with the present invention. In an exemplary embodiment, the method 600 is suitable for use to form the cross-point arrays shown in FIGS. 3-4 described above.

At block 602, multiple layers of material are deposited to form stacked layers. For example, in an exemplary embodiment, the process steps described with respect to FIG. 3A above are performed.

At block 604, a first lithography operation is performed to form a photoresist mask on top of the stacked layers for cell columns, word lines and bit lines. The stacked layers are then etched through to form the cell columns, word lines and bit lines and the resulting space is filled with an insulator. For example, in an exemplary embodiment, the process steps described with respect to FIG. 3B-D above are performed. Precise alignment occurs because the cell patterns, word lines, and bit lines of all the multiple layers are defined by one lithography step that forms the trench hole defining the cell columns, word lines, and bit lines, and then deposits multiple layers into the trench hole. Thus, the cell patterns of multiple layers are all self-aligned.

At block 606, the word line region and bit line region are masked. For example, in an exemplary embodiment, the process steps described with respect to FIG. 3E above are performed.

At block 608, the process 500 above is performed to form cross-point word lines and bit lines in the column area. For example, in an exemplary embodiment, the process steps 506-512 described above with respect to FIG. 3F above are performed. The results are shown in FIGS. 3G-H.

At block 610, the column area is masked and insulator material is removed from bit line and word line regions. For example, in an exemplary embodiment, the process steps described with respect to FIG. 4A-B above are performed.

At block 612, the cell layers between the word lines and bit lines are etch away to expose bit lines and word lines. For example, in an exemplary embodiment, the process steps described with respect to FIG. 4C above are performed.

At block 614, the space between bit lines and word lines is filled with an insulator. For example, in an exemplary embodiment, the process steps described with respect to FIG. 4D above are performed.

Thus, the method 600 operates to form a cross-point array having word lines and bit lines that can be connected to peripheral circuitry in accordance with the present invention. It should be noted that the method 600 is exemplary and that any of the disclosed operations may be combined, rearranged, added to, deleted, and/or modified within the scope of the embodiments.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A method comprising:
forming stacked layers;
performing a first lithography operation on the stacked layers to form cell columns;
performing a second lithography operation on the cell columns to form first vertical openings that are filled with first conductor layers to form one or more word line connections in a first direction; and
performing a third lithography operation on the cell columns to form second vertical openings that are filled with second conductor layers to form one or more bit line connections in a second direction.

2. The method of claim 1, wherein the operation of forming comprising forming the stacked layers to comprise at least one of conductor layers, memory element layers and selector layers.

3. The method of claim 1, wherein the operation of performing the first lithography operation comprises:
forming a photoresist mask on top of the stacked layers;
etching through all the stacked layers to form the cell columns; and
filling space between the cell columns with an insulator.

4. The method of claim 3, wherein the operation of performing the second lithography operation comprises:
forming a first photoresist mask on top of the stacked layers;
etching through all the stacked layers to form the first vertical openings;
depositing the conductor layers into the first vertical openings to form the one or more word line connections in the first direction.

5. The method of claim 4, wherein the operation of depositing comprises depositing insulator layers between the conductor layers.

6. The method of claim 3, wherein the operation of performing the third lithography operation comprises:
forming a second photoresist mask on top of the stacked layers;
etching through all the stacked layers to form the second vertical openings;
depositing the conductor layers into the second vertical openings to form the one or more bit line connections in the second direction.

7. The method of claim 6, wherein the operation of depositing comprises depositing insulator layers between the conductor layers.

8. The method of claim 1, wherein the method forms a 3D cross-point array.

9. A method comprising:
forming stacked layers;
performing a first lithography operation to form a photoresist mask for cell columns, word lines and bit lines on top of the stacked layers;
etching through stacked layers to form the cell columns, the word lines and the bit lines;
filling space between the cell columns, the word lines and the bit lines with an insulator;
performing a second lithography operation on the stacked layers for the cell columns to form first vertical openings that are filled with first conductor layers to form one or more word line connections in a first direction; and
performing a third lithography operation on the stacked layers for the cell columns to form second vertical openings that are filled with second conductor layers to form one or more bit line connections in a second direction.

10. The method of claim 9, further comprising performing a fourth lithography operation on the stacked layers for the word lines to form word line connectors.

11. The method of claim 10, further comprising etching away a portion of the stacked layers between the word line connectors to form exposed word line connectors.

12. The method of claim 11, further comprising filling space between the exposed word line connectors with an insulator.

13. The method of claim 10, further comprising performing a fifth lithography operation on the stacked layers for the bit lines to form bit line connectors.

14. The method of claim 13, further comprising etching away a portion of the stacked layers between the bit line connectors to form exposed bit line connectors.

15. The method of claim 15, further comprising filling space between the exposed bit line connectors with an insulator.

16. A 3D cross-point array formed by performing the operations of:
forming stacked layers;
performing a first lithography operation on the stacked layers to form cell columns wherein memory cells in each column are aligned;
performing a second lithography operation on the stacked layers to form first vertical openings that are filled with first conductor layers to form one or more word line connections in a first direction; and
performing a third lithography operation on the stacked layers to form second vertical openings that are filled with second conductor layers to form one or more bit line connections in a second direction.
